(19) United States
(12) Patent Application Publication
(10) Pub. No.: US 2010/0188169 A1
(43) Pub. Date: Jul. 29, 2010

(54) Reactance Varying Device

(75) Inventors: Sorwar Hossain, Kawasaki (JP); Yasuyuki Oishi, Kawasaki (JP)

Correspondence Address: HANIFY & KING PROFESSIONAL CORPORATION, 1055 Thomas Jefferson Street, NW, Suite 400, WASHINGTON, DC, 20007, US

(73) Assignee: FUJITSU LIMITED, Kawasaki-shi, Kanagawa (JP)

(21) Appl. No.: 12/665,177

(22) PCT Filed: Aug. 7, 2007
(86) PCT No.: PCT/JP2007/065800

§ 371 Date: Dec. 17, 2009

(51) Int. Cl. H03H 7/01

(52) U.S. Cl. 333/175

(57) ABSTRACT

A reactance varying device comprises a voltage-controlled variable-capacitance circuit, a biasing circuit and an impedance transformer. The biasing circuit has a virtual AC ground node, which acts as a gateway to supply a bias voltage to the variable-capacitance circuit. The impedance transformer separates the variable-capacitance circuit from the AC ground node, as well as provides an inductive element to form a reactance varying LC tank.

### TECHNICAL FIELD

The present invention relates to a reactance varying device, and more specifically a reactance varying passive circuit to vary reactance in radio frequency (RF) and microwave application for instance in a planar electronically steerable parasitic array radiator (ESPAR) antenna for adaptive-beam forming or in an adaptive impedance matching circuit.

### BACKGROUND ART

A low profile and low loss reactance varying circuit can be essential for different applications in RF and microwave for instance an adaptive beam forming in an ESPAR antenna, where the coupling in the parasitic passive elements are controlled by changing the input impedance of each parasitic element. The reactance varying circuit is also widely used in the adaptive impedance matching circuit to obtain a maximum radiated power of an antenna. The reactance varying circuit is to be designed so that its effective reactance varying range is not affected by the associated RF circuit or it does not incur any RF loss while it varies the reactance in a desired operation range to obtain a reasonable performance in an RF or Microwave circuit.

A simple way to form a reactance varying circuit could be that it uses a varactor diode together with a bias tee circuit for a direct-current (DC) voltage supply. A varactor diode is a reverse bias diode that produces a variable capacitance with applied DC voltage. A common practice for a bias tee is to make high impedance isolation between the DC part and the RF part. This high impedance isolation can be realized by using an open inductive stub, or a radial stub together with a quarter wavelength high impedance line (see Patent Document 1, 2, and 3), or simply a high resistance chip resistor between the RF part and the DC part.

When a varactor diode is connected across the biasing circuit in a reactance varying circuit, any parasitic impedance that may appear due to the biasing circuit causes a leakage that incurs an RF loss as well as causes a narrowing down effect of the reactance variation range of the varactor diode.

FIG. 1 shows a simplified conventional reactance varying circuit in an RF application. The reactance varying circuit consists of two parts, variable-capacitance circuit 103 and biasing circuit 104, and is connected to RF antenna 101 through transmission line 102. The variable-capacitance circuit 103 includes a varactor diode with variable reactance −jX and the biasing circuit 104 includes a bias tee circuit. The purpose of the biasing circuit 104 is to supply DC voltage to the variable-capacitance circuit 103 while it prevents any RF leakage from the RF part to the DC part.

The conventional biasing circuit 104 uses high impedance isolation, for instance open stub choke that acts like a series inductance, radial stub choke with a quarter wavelength section of high impedance transmission line that acts like an open stub, or simply a high resistance chip resistor. Due to high impedance isolation the biasing circuit 104 may produce some parasitic impedance. It is denoted by Zpp and Zps that appear in parallel and series respectively with the biasing circuit 104. As a result the parasitic impedance disturbs a desired variation of reactance range as well as it causes some unwanted RF losses in the biasing circuit 104.

### Patent Document 1: Japanese Patent Application Publication No. 11-340737

### Patent Document 2: Japanese Patent Application Publication No. 58-141001

### Patent Document 3: Japanese Patent Application Publication No. 61-002340

### DISCLOSURE OF INVENTION

An object of the present invention is to remove the parasitic impedance due to a biasing circuit provided in a reactance varying device.

A reactance varying device according to the present invention comprises a voltage-controlled variable-capacitance circuit, a biasing circuit and an impedance transformer. The biasing circuit has an alternating-current (AC) ground node and supplies a bias voltage to the variable-capacitance circuit. The impedance transformer separates the variable-capacitance circuit from the AC ground node.

Since the biasing circuit has an AC ground node, any parasitic impedance that appears across the biasing circuit will be eliminated and unwanted high frequency signal losses such as RF losses will be small. Furthermore, the variable-capacitance circuit and the impedance transformer form an LC tank and provide a reactance variation in a wider range to a high frequency signal.

### BRIEF DESCRIPTION OF DRAWINGS

FIG. 1 is a block diagram of a simplified conventional reactance varying circuit;

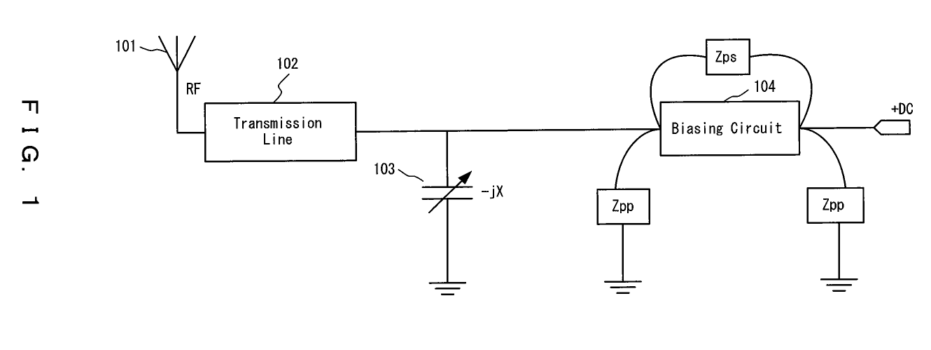

FIG. 2 is a block diagram of a reactance varying circuit according to an embodiment of the present invention;

FIG. 3 is a circuit diagram of an approximate lumped element equivalent model of the reactance varying circuit;

FIG. 4 is a layout view of a planar circuit that is realized for the reactance varying circuit;

FIG. 5 is a perspective view of the planar circuit for the reactance varying circuit;

FIG. 6 is a graph showing a simulation result regarding the frequency dependence of the DC to RF isolation characteristic of a resonating dual choke circuit; and

FIG. 7 is a graph showing a simulation result regarding the frequency dependence of the return loss characteristic of the resonating dual choke circuit.

### BEST MODE OF CARRYING OUT THE INVENTION

A best mode for carrying out the present invention is hereinafter described in detail with reference to the drawings.

In an embodiment of the present invention a new technique is employed for the bias tee circuit that is different from the conventional one. The new technique proposes an RF ground isolation technique instead of high impedance for the bias tee circuit. The RF ground together with an impedance transformer between the RF part and the DC part is proposed to realize a reactance varying passive RF circuit that produces a desired range of reactance variation while keeping the RF loss negligibly small.

The reactance varying circuit is realized as an integrated passive RF circuit on a low profile printed circuit board (PCB) technology that consists of a variable-capacitance circuit, an impedance transformer, and a parasitic impedance free RF ground biasing circuit. The biasing circuit is realized by a resonating dual choke (RDC) circuit, which has a zero input impedance hence any parasitic impedance that appears across the biasing circuit will be eliminated. The RDC circuit is realized, for example, with two non-resonating open stub chokes with different lengths or electrical lengths. Because the respective chokes are designed with two different lengths, there exists two transmission zeros for the RDC circuit. The chokes are cascaded with a section of transmission line of a suitable length in between so that both chokes are physically separated from each other and also the RDC circuit holds the isolation operation between RF and DC through a band of frequency between two poles.

Since the RDC circuit is designed to obtain an RF ground, it should not be directly connected across the variable-capacitance circuit. An impedance transformer named as Z-transformer, which is a section of a transmission line, is inserted between the variable-capacitance circuit and the RDC circuit. Besides providing an RF ground between RF and a DC supply, the RDC has another special feature to assist the reactance varying circuit forming an LC tank by combining the variable-capacitance circuit and the Z-transformer. The Z-transformer acts as an inductor in parallel, hence the LC tank varies the reactance in a wider range.

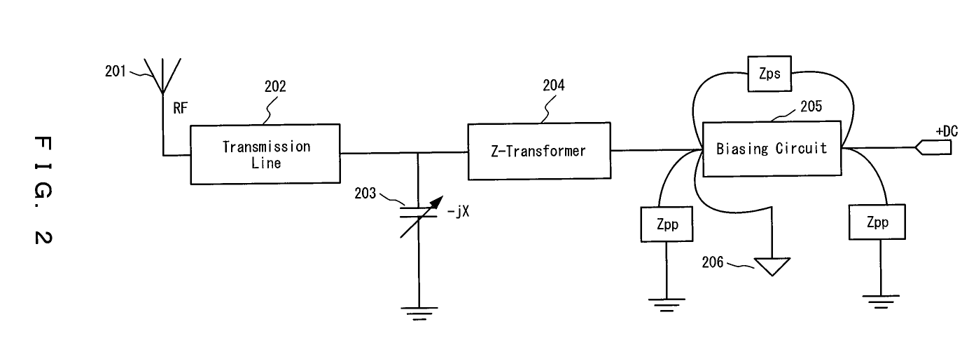

FIG. 2 shows a block diagram of such a reactance varying circuit. The reactance varying circuit consists of variable-capacitance circuit 203, Z-transformer 204 and biasing circuit 205, and is connected to RF antenna 201 through transmission line 202. For example, the variable-capacitance circuit 203 includes a varactor diode and the biasing circuit 205 includes an RDC circuit.

RF ground biasing has been proposed as the key point of this circuit. Due to RF ground 206 there will be no parasitic impedance that may exist in the biasing circuit since all parasitic impedance Zpp and Zps will be shorted out. Although the biasing is realized by an RF short it will maintain a DC voltage supply path to the variable-capacitance circuit 203 while it blocks the RF signal leakage to the DC voltage supply. Since a short circuit will appear across the variable-capacitance circuit 203, the RF ground 206 needs to be separated from the variable-capacitance circuit 203. A section of transmission line 204 named as Z-transformer is provided to separate the variable-capacitance circuit 203 and the RF ground 206.

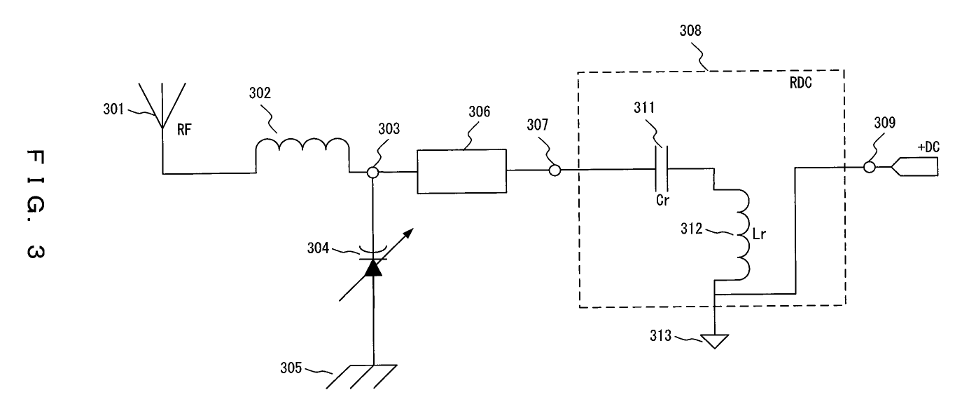

FIG. 3 shows an approximate lumped element equivalent model of the reactance varying circuit to explain the working mechanism of the circuit. The lumped elements are approximated as an ideal case by neglecting all loss equivalent parameters. Dotted block 308 shows the approximate lumped element equivalent model for the RDC circuit and includes approximate lumped capacitor 311 and inductor 312 with capacitance Cr and inductance Lr, respectively. At the desired design frequency, the capacitor 311 and the inductor 312 together produce a series resonance hence the RDC block 308 realizes an RF ground 313. While it resonates, the RDC block 308 produces zero input impedance at node 307 as Lr and Cr will disappear.

Node 309 represents a point where a DC voltage supply is connected. Z-transformer 306 is connected between nodes 303 and 307. Since the Z-transformer 306 is a section of transmission line terminated at the node 307, which is an RF ground node, it acts like an inductor. Varactor diode 304 is connected between the node 303 and DC ground 305. The DC ground 305 is different from the RF ground 313. Therefore, the Z-transformer 306 sees an RF ground to form an LC tank circuit together with the varactor diode 304. The LC tank circuit produces the input reactance variation at the node 303. As the supplied DC voltage changes at the node 309, the capacitance value of the varactor diode 304 changes, hence the varactor diode 304 produces the reactance variation across the LC tank circuit at the node 303.

Inductor 302 is an approximation for a section of 50 ohm transmission line that connects the feeding point of antenna 301 to the reactance varying node 303. The antenna 301 could be replaced with an RF circuit.

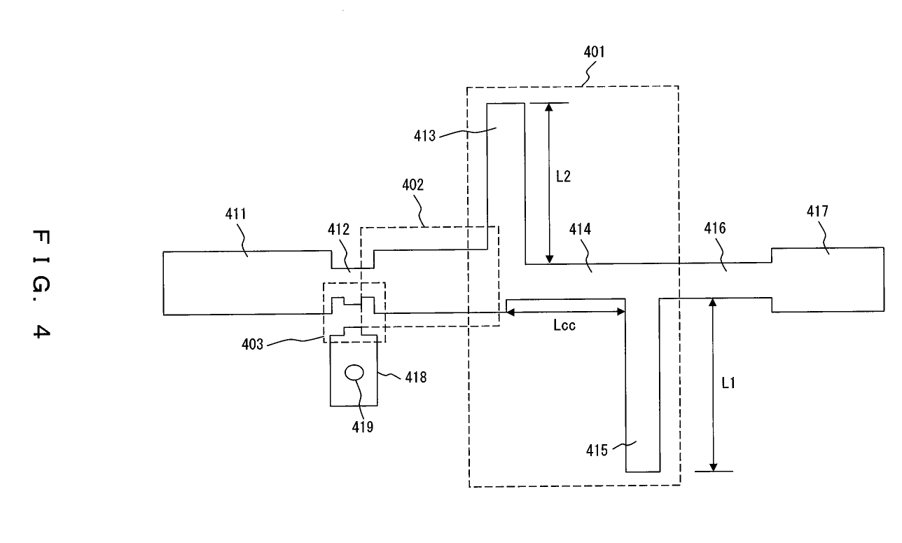

FIG. 4 shows a top view of a layout example of the reactance varying passive RF circuit. Dotted block 401 represents the RDC block 308 of the reactance varying circuit and includes two microstrip open stubs 413 and 415. Both stubs are separated by a section of transmission line 414. The stub 415 has length L1, which is preferably greater than length L2 of the stub 413. The stub 415 acts as an inductive choke at the desired design frequency hence the length L1 is preferably greater than one-quarter of the substrate wavelength of an RF signal. The length L2 of the stub 413 is preferably less than one-quarter of the substrate wavelength so that it acts as a capacitive choke. The transmission line section 414 has length Lcc, which is also preferably less than one-quarter of the substrate wavelength.

As a design step L1 and the width of the stub 415 is decided at the beginning based on the design frequency, and later both L2 and Lcc are designed simultaneously in an electromagnetic simulation so that the RDC block 308 realizes an RF ground at the node 307 in FIG. 3. Since L1 and L2 are two different lengths, the RDC block 308 possesses two different transmission zeros or poles. The pole that appears at a lower frequency is due to the inductive choke of the stub 415 while the other pole that appears at a higher frequency is due to the capacitive choke of the stub 413. So the RDC block 308 holds isolation between the DC and the RF over a band of frequency. The transmission zero or pole due to the inductive choke should appear either at the designated design frequency or slightly below the design frequency i.e. the designated operating frequency of the reactance varying circuit should fall in between the poles of the RDC block 308.

Dotted block 402 corresponds to the Z-transformer 306 that prevents the varactor diode 304 from seeing the RF ground. A suitable length for the block 402 is below or equal to one-eighth of the substrate wavelength. The widths of the stubs 413 and 415, the transmission line section 414 and the block 402 can be different. Since the block 402 sees the block 401 as an RF short, it acts like an inductor to form an LC tank with the varactor diode 304. Gap 403 represents a place to install the varactor diode 304. A thin section of transmission line 412 provides a soldering pad for the varactor diode 304 as well as it provides a discontinuity between transmission line section 411 and the block 402. The reverse bias end of the varactor diode 304 is connected to the transmission line section 412 and the other end is connected to ground-pad 418, which is connected to the bottom surface of the PCB through low inductance via-hole 419.

The transmission line section 411 connects the reactance varying circuit to the feeding point of the antenna 301 or an RF circuit of interest. Part 416 is to make a bias tee circuit and has the same width as that of the transmission line section 414. The part 416 does not affect the reactance variation, and it only provides a path for the DC voltage supply. Part 417 acts as a DC voltage supply connecting pad.

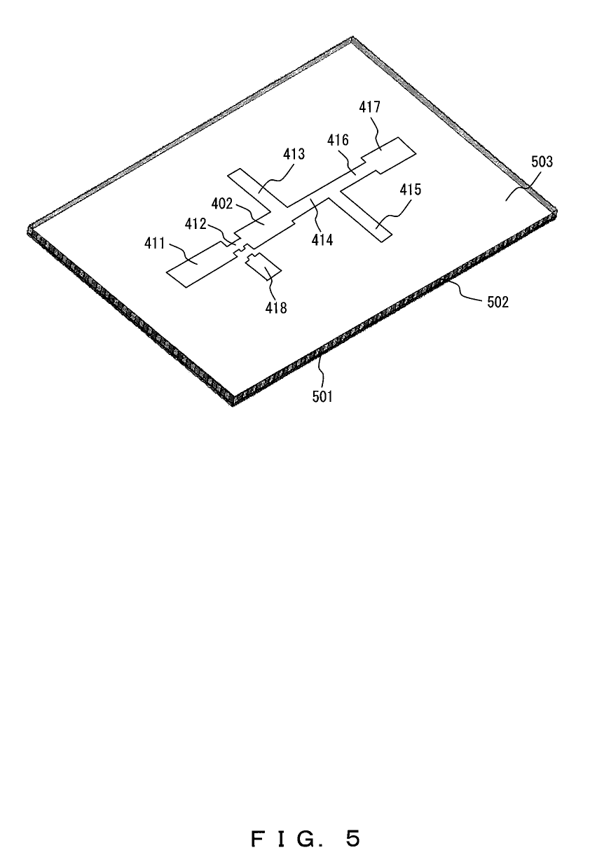

FIG. 5 shows a perspective view of the reactance varying passive RF circuit on a PCB. The top surface 503 contains the reactance varying passive RF circuit shown in FIG. 4. The substrate dielectric material 502 of the PCB is sandwiched between the top surface 503 and bottom surface 501. The bottom surface 501 contains the ground plane which provides the DC ground 305.

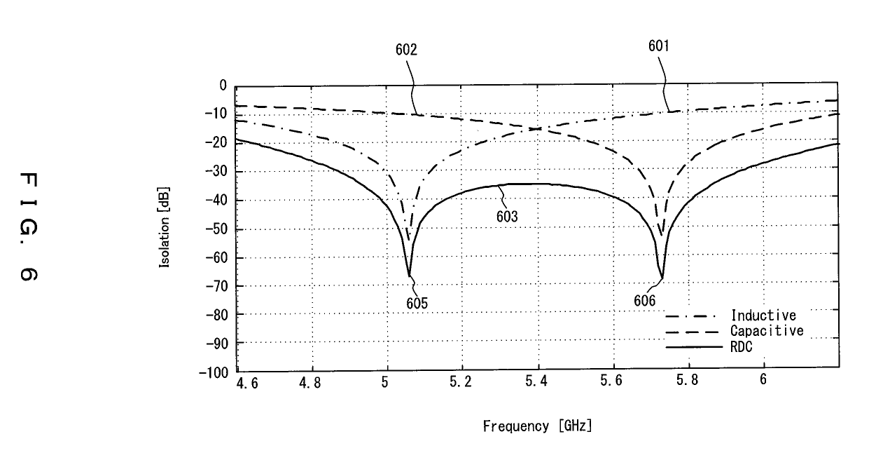

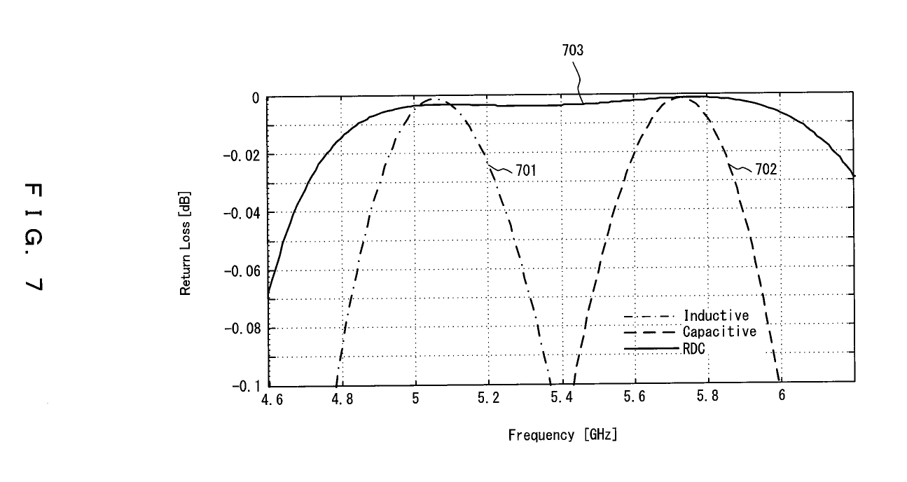

FIGS. 6 and 7 show the frequency characteristics of the RDC block 308. FIG. 6 illustrates the isolation between RF and DC in terms of the transmission coefficient S21 between the nodes 307 and 309 in units of dB. For an illustration purpose the RDC block 308 is designed at 5.06 GHz. Curve 601, 602 and 603 represent the isolation due to the inductive choke, the capacitive choke and the RDC, respectively. The curve 603 shows that the RDC circuit has two transmission zeros or poles 605 and 606. The first pole 605, which is appearing at the design frequency, is a contribution due to the stub 415. The second pole 606 is obtained due to an optimization of the length L2 and the width of stub 413 as well as the length Lcc of the transmission line section 414 to realize a zero input impedance of the RDC circuit.

FIG. 7 illustrates the return loss in terms of the reflection coefficient S11 at the input node 307 of the RDC circuit in units of dB. Curve 701, 702 and 703 represent the return loss due to the inductive choke, the capacitive choke and the RDC, respectively. As it is shown that the return is quite small throughout the operating band, the RDC will have a negligibly small RF loss. However, it needs to clarify that the illustrated return loss has been obtained in simulation for an ideal situation. A fabricated real RDC will have some loss due to the conductor and dielectric substrate.

As described above, an RDC circuit has been successfully proposed for a reactance varying circuit. The circuit supports a broadband operation and produces a wide reactance variation that can be used for an ESPAR antenna or an adaptive impedance matching circuit.

1. A reactance varying device, comprising:
a voltage-controlled variable-capacitance circuit;
a biasing circuit having an alternating-current ground node, for supplying a bias voltage to the variable-capacitance circuit; and
an impedance transformer for separating the variable-capacitance circuit from the alternating-current ground node.

2. The reactance varying device according to claim 1, wherein
the biasing circuit includes an inductive choke and a capacitive choke which produce a series resonance to realize the alternating-current ground node.

3. The reactance varying device according to claim 1 or 2, wherein
the biasing circuit includes a pair of open stubs and a section of transmission line separating the open stubs, which form a resonating circuit to realize the alternating-current ground node.

4. The reactance varying device according to claim 3, wherein
The resonating circuit acts as an alternating current ground biasing tee circuit to supply the bias voltage to the variable-capacitance circuit.

5. The reactance varying device according to claim 3, wherein
the biasing circuit has a direct-current voltage input node supplied with a direct-current voltage and the resonating circuit blocks an alternating-current signal leakage to the direct-current voltage input node.

6. The reactance varying device according to claim 3, wherein
the open stubs have different lengths to each other.

7. The reactance varying device according to claim 6, wherein
the biasing circuit has a direct-current voltage input node supplied with a direct-current voltage and a length of the open stub closer to the direct-current voltage input node is greater than a length of the open stub closer to the impedance transformer.

8. The reactance varying device according to claim 6, wherein
a length of one of the open stubs is greater than one-quarter of a wavelength of an alternating-current signal.

9. The reactance varying device according to claim 8, wherein
the length of the one of the open stubs is designed such that the one of the open stubs acts as an inductive choke with a transmission zero at or below an operating frequency of the reactance varying device.

10. The reactance varying device according to claim 6, wherein
a length of one of the open stubs is less than one-quarter of a wavelength of an alternating-current signal.

11. The reactance varying device according to claim 10, wherein
the length of the one of the open stubs is designed such that the one of the open stubs acts as a capacitive choke with a transmission zero at a frequency higher than an operating frequency of the reactance varying device.

12. The reactance varying device according to claim 6, wherein
a length of the section of transmission line is less than one-quarter of a wavelength of an alternating-current signal.

13. The reactance varying device according to claim 1, wherein
the impedance transformer is a section of transmission line.

14. The reactance varying device according to claim 13, wherein
a length of the impedance transformer is less than or equal to one-eighth of a wavelength of an alternating-current signal.

15. The reactance varying device according to claim 1, wherein
the variable-capacitance circuit and the impedance transformer together provide a reactance variation to a high frequency signal while the alternating-current ground node acts as a high frequency signal ground.
